(19) United States
(12) Patent Application Publication
(10) Pub. No.: US 2008/0054293 A1
(43) Pub. Date: Mar. 6, 2008

(54) NITRIDE SEMICONDUCTOR AND METHOD FOR MANUFACTURING THE SAME

(75) Inventors: Chih-Ming Lai, Pingtung County (TW); Po-Chun Liu, Taichung County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(73) Assignee: INDUSTRIAL TECHNOLOGY RESEARCH INSTITUTE, Hsinchu (TW)

(21) Appl. No.: 11/562,421

(22) Filed: Nov. 22, 2006

(30) Foreign Application Priority Data
Aug. 31, 2006 (TW) 95132151

(51) Int. Cl. H01L 33/00

(52) U.S. Cl. 257/103

(57) ABSTRACT

A method of manufacturing a nitride semiconductor substrate is provided. A partial surface treatment process is performed to rough a portion of a surface of a substrate. Next, a nitride semiconductor layer is formed over the substrate. Since the nitride semiconductor layer simply grows on the unroughened surface of the substrate through selective area epitaxy growth and lateral epitaxy growth, some of the threading dislocations in the nitride semiconductor layer are blocked. Thereby, the threading dislocation density of the grown nitride semiconductor layer is reduced.

### CROSS-REFERENCE TO RELATED APPLICATION

This application claims the priority benefit of Taiwan application serial no. 95132151, filed Aug. 31, 2006. All disclosure of the Taiwan application is incorporated herein by reference.

### BACKGROUND OF THE INVENTION

1. Field of the Invention

The present invention relates to a group III-V semiconductor substrate and the method of manufacturing the same, and more particularly to a nitride semiconductor substrate and the method of manufacturing the same.

2. Description of Related Art

In the recent years, light emitting diodes (LED) and laser diodes (LD) are now prevailing in commercial use. For example, a mixture of blue and yellow phosphors made of gallium nitride (GaN) is capable of generating white light, which leads to a high luminance and substantially low power consumption over a conventional light bulb. In addition, the LED has a lifetime of more than tens of thousand hours, longer than that of the conventional light bulb.

In the current market, the LEDs emitting red light, green light, blue light, or ultraviolet light are mostly made of gallium nitride (GaN) series compound. However, since aluminum oxide (sapphire) substrates and the GaN series compound have considerable differences in lattice constants, thermal expansion coefficients, and chemical properties, the GaN layer growing on a heterogeneous substrate e.g. a silicon substrate, a silicon carbide (SiC) substrate, or an aluminum oxide (Al₂O₃) substrate may encounters line defects and dislocations. The dislocations extend together with the increase in thickness of the growing GaN layer, resulting in formation of threading dislocations. Said defects would affect laser performance and reduce the lifetime of the ultraviolet LEDs and of the GaN-series compound.

Several substrate structures are then developed to reduce the threading dislocations according to the prior art. FIG. 1 is a simplified sectional view illustrating a conventional group III nitride substrate. Referring to FIG. 1, a GaN buffer layer 102 is disposed on a substrate 100, and several barrier structures 104 are disposed on the GaN buffer layer 102. A semiconductor layer 106 i.e. a GaN epitaxy layer then grows on the GaN buffer layer 102 excluding the barrier structures 104 disposed thereon and covers the barrier structures 104. Through the depositions of the barrier structures 104, some dislocations in the substrate structure are blocked, so that a portion of the GaN epitaxy layer disposed on the barrier structures generates no threading dislocations. However, the barrier structures 104 are formed through performing a photolithography and etching process for once at least, and vacuum facilities are required, complicating the manufacturing process and increasing the cost.

FIG. 2 is a simplified sectional view illustrating another conventional group III nitride substrate. Referring to FIG. 2, a buffer layer 202 and a seed layer 204 are formed on the substrate 200. Trenches 206 passing through the buffer layer 202 and the seed layer 204 are then formed in the substrate 200. Namely, the buffer layer 202 and the seed layer 204 are patterned and thereby striped or point-like structures are formed. A selective lateral overgrowth technique with the use of a heterogeneous structure is called “pendeo-epitaxy” (PE) whereby the GaN epitaxy layer 208 is simply suspended from and laterally grows on the sidewalls of the striped seed layer 204. Then, the GaN epitaxy layer 208 covers the striped seed layer 204 so as to block several threading dislocations in a vertical direction. Similar to the barrier structures 104 illustrated in FIG. 1, trenches 206 passing through the buffer layer 202 and the seed layer 204 are formed through performing a photolithography and etching process for once at least, and vacuum facilities are required, complicating the manufacturing process and increasing the cost.

### SUMMARY OF THE INVENTION

The present invention is to provide a method of manufacturing a nitride semiconductor substrate so as to reduce the manufacturing cost.

The present invention is to provide a method of manufacturing a nitride semiconductor substrate so as to simplify the manufacturing process.

The present invention is to provide a nitride semiconductor substrate which is capable of reducing the dislocation density of the nitride semiconductor layer.

The invention provides a method of manufacturing a nitride semiconductor substrate. A partial surface treatment process is then performed to roughen a portion of a surface of a substrate. Next, a nitride semiconductor layer is formed over the substrate.

The invention further provides a method of manufacturing a nitride semiconductor substrate. The method comprises steps of providing a substrate having a mirror surface. A surface treatment process is then performed to rough a portion of the mirror surface of the substrate and to form a rough surface. Next, a nitride semiconductor layer is formed over the substrate.

The present invention further provides a nitride semiconductor substrate comprising a substrate and a nitride semiconductor layer. A surface of the substrate comprises a mirror region and a rough region. The nitride semiconductor layer is disposed over the substrate and connected to the mirror region of the substrate.

In the present invention, the nitride semiconductor layer is on the mirror region of the substrate by selective area epitaxy growth and lateral epitaxy growth. Hence, some of the threading dislocations in the nitride semiconductor layer are blocked. Thereby, the threading dislocation density of the grown nitride semiconductor layer is reduced. Furthermore, the present invention directly damages a portion of the surface of the substrate through a physical damage process rather than blocks some of the threading dislocations in the nitride semiconductor layer by additionally forming trenches or barrier structures on the substrate. Accordingly, the method disclosed in the present invention reduces the manufacturing costs and simplifies the manufacturing process.

In order to the make aforementioned and other objects, features and advantages of the present invention comprehensible, a preferred embodiment accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a simplified sectional view illustrating a group III nitride substrate according to the prior art.

FIG. 2 is a simplified sectional view illustrating another group III nitride substrate according to the prior art.

FIGS. 3A to 3B are schematic sectional views illustrating a method of manufacturing a nitride semiconductor substrate according to one preferred embodiment of the present invention.

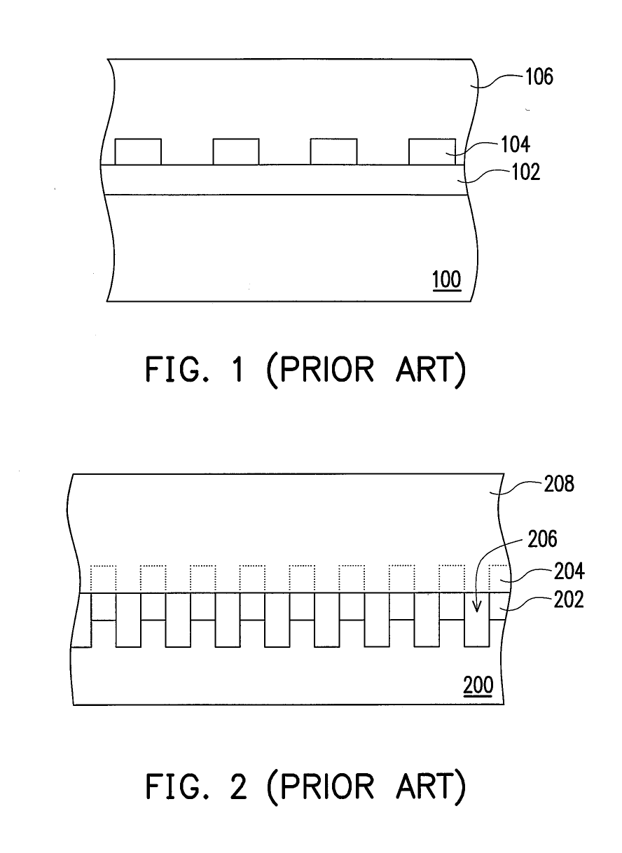

### DESCRIPTION OF EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

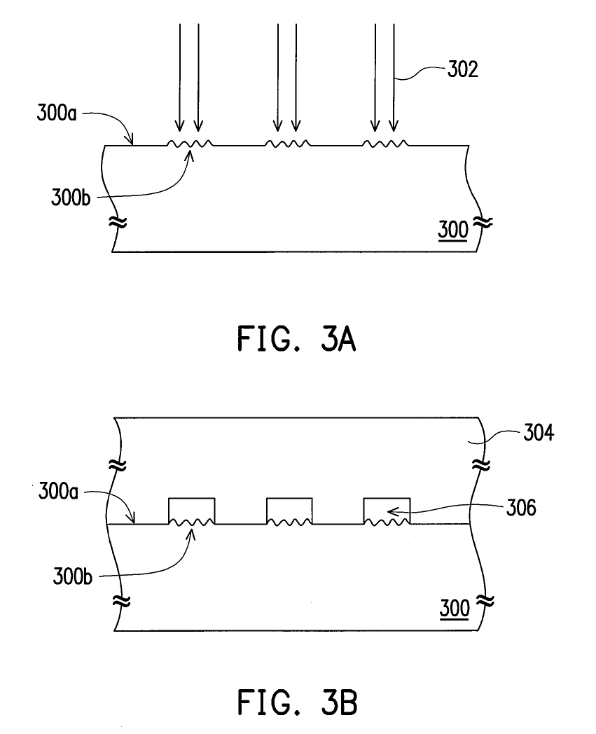

FIGS. 3A to 3B are schematic sectional views a method of manufacturing a nitride semiconductor substrate according to one embodiment of the present invention. Firstly, referring to FIG. 3A, a substrate 300 is provided. The material of the substrate 300 is selected from one group comprising silicon, silicon carbide (SiC), aluminum oxide (Al₂O₃), sapphire, gallium nitride (GaN), aluminum nitride (AlN), glass, quartz, zinc oxide (ZnO), magnesium oxide (MgO), and lithium gallium oxide (LiGaO₂), for example. In addition, the substrate 300 comprises a smooth mirror surface 300a.

Next, a surface treatment process 302 is performed to convert a portion of the mirror surface of the substrate 300 to a rough region 300b. The surface treatment process 302 refers to a partial surface treatment process, comprising a step of physically damaging a portion of the mirror surface 300a of the substrate 300. The partial surface treatment process preferably includes a step of irradiating the substrate 300 with the use of a coherent electromagnetic wave so as to damage the irradiated mirror surface. Further, said coherent electromagnetic wave can be a laser beam. Namely, the laser beams are converged in one spot of the substrate 300 and successively damage a portion of the surface structure of the substrate 300 through a transient, high energy emission. Thereby, the rough region 300b is formed.

It should be noted that after the surface treatment process 302 is performed, a mirror region 300a and a rough region 300b are formed on the surface of the substrate 300.

Thereafter, referring to FIG. 3B, a nitride semiconductor layer 304 is formed over the substrate 300. The material of the nitride semiconductor layer 304 is selected from one group consisting of gallium nitride (GaN), indium nitride (InN), aluminum nitride (AlN), aluminum gallium nitride, indium gallium nitride, indium aluminum nitride, and aluminum indium gallium nitride. The method of forming the nitride semiconductor layer 304 comprises an epitaxy process. The surface of the substrate 300 comprises the mirror region 300a and the rough region 300b, and the surface of the rough region 300b is uneven. Hence, as the epitaxy process is performed to form the nitride semiconductor layer 304, the nitride semiconductor layer 304 does not grow on the rough region 300b but on the mirror region 300a of the substrate 300. In other words, the nitride semiconductor layer 304 grows on the selective regions of the substrate. When the nitride semiconductor layer 304 grows upward through the epitaxy process, it also grows in a lateral direction to cover the surface of the substrate completely. Namely, the nitride semiconductor layer 304 is simply connected to the mirror region 300a of the substrate 300 and hung across the rough region 300b of the substrate 300. As a result, a space 306 is formed above the rough region 300b of the substrate 300 and below the nitride semiconductor layer 304.

Since the nitride semiconductor layer 304 is formed on the substrate 300 by selective area epitaxy growth and lateral epitaxy growth, some of the threading dislocations in the nitride semiconductor layer are blocked. Thereby, the threading dislocation density of the grown nitride semiconductor layer is reduced. The dislocation density of the nitride semiconductor layer according to the present invention is less than 10⁹ cm⁻².

Furthermore, comparing with the prior art, the present invention directly damages a portion of the surface of the substrate through a physical damage process rather than blocks some of the threading dislocations in the nitride semiconductor layer by additionally forming trenches or barrier structures on the substrate. Accordingly, the method disclosed in the present invention reduces the manufacturing costs and simplifies the manufacturing process.

Although the present invention has been disclosed above by the preferred embodiments, they are not intended to limit the present invention. Anybody skilled in the art can make some modifications and alteration without departing from the spirit and scope of the present invention. Therefore, the protecting range of the present invention falls in the appended claims.

What is claimed is:

1. A method of manufacturing a nitride semiconductor substrate, comprising:
providing a substrate;
performing a surface treatment process to rough a portion of a surface of the substrate; and
forming a nitride semiconductor layer over the substrate.

2. The method of manufacturing the nitride semiconductor substrate of claim 1, wherein the material of the substrate is selected from one group comprises silicon, silicon carbide (SiC), aluminum oxide (Al₂O₃), sapphire, gallium nitride (GaN), aluminum nitride (AlN), glass, quartz, zinc oxide (ZnO), magnesium oxide (MgO), and lithium gallium oxide (LiGaO₂).

3. The method of manufacturing the nitride semiconductor substrate of claim 1, wherein the surface treatment process comprises a step of irradiating the portion of the surface of the substrate with the use of a coherent electromagnetic wave to damage an irradiated surface structure.

4. The method of manufacturing the nitride semiconductor substrate of claim 1, wherein the surface treatment process comprises a step of physically damaging the portion of the surface of the substrate.

5. The method of manufacturing the nitride semiconductor substrate of claim 1, wherein the material of the nitride semiconductor layer is selected from one group consisting of gallium nitride (GaN), indium nitride (InN), aluminum nitride (AlN), aluminum gallium nitride, indium gallium nitride, indium aluminum nitride, and aluminum indium gallium nitride.

6. The method of manufacturing the nitride semiconductor substrate of claim 1, wherein the step of forming the nitride semiconductor layer comprises performing a selective area epitaxy growth and lateral epitaxy growth process on an unroughened surface of the substrate to form the nitride semiconductor layer.

7. A method of manufacturing a nitride semiconductor substrate, comprising:
providing a substrate, wherein the substrate has a mirror surface;
performing a surface treatment process to rough a portion of the mirror surface of the substrate and forming a rough surface; and
forming a nitride semiconductor layer over the substrate.

8. The method of manufacturing the nitride semiconductor substrate of claim 7, wherein the material of the substrate is selected from one group comprises silicon, silicon carbide (SiC), aluminum oxide (Al₂O₃), sapphire, gallium nitride (GaN), aluminum nitride (AlN), glass, quartz, zinc oxide (ZnO), magnesium oxide (MgO), and lithium gallium oxide (LiGaO₂).

9. The method of manufacturing the nitride semiconductor substrate of claim 7, wherein the material of the nitride semiconductor layer is selected from one group consisting of gallium nitride (GaN), indium nitride (InN), aluminum gallium nitride, indium gallium nitride, indium aluminum nitride, and aluminum indium gallium nitride.

10. The method of manufacturing the nitride semiconductor substrate of claim 7, wherein a method of forming the rough surface comprises physically damaging a portion of the mirror surface of the substrate.

11. The method of manufacturing the nitride semiconductor substrate of claim 10, wherein the physical damage process comprises irradiating the portion of the mirror surface of the substrate with the use of a coherent electromagnetic wave.

12. The method of manufacturing the nitride semiconductor substrate of claim 7, comprising steps of performing a selective area epitaxy growth and lateral epitaxy growth process on the mirror surface excluding the rough surface disposed thereon to form the nitride semiconductor layer.

13. A nitride semiconductor substrate, comprising:
a substrate, wherein a surface of the substrate comprises a mirror region and a rough region; and
a nitride semiconductor layer disposed over the substrate and connected to the mirror region of the substrate.

14. The nitride semiconductor substrate of claim 13, wherein the nitride semiconductor layer is hung across the rough region.

15. The nitride semiconductor substrate of claim 13, wherein the material of the substrate is selected from one group comprises silicon, silicon carbide (SiC), aluminum oxide (Al₂O₃), sapphire, gallium nitride (GaN), aluminum nitride (AlN), glass, quartz, zinc oxide (ZnO), magnesium oxide (MgO), and lithium gallium oxide (LiGaO₂).

16. The nitride semiconductor substrate of claim 13, wherein a material of the nitride semiconductor layer is selected from one group consisting of gallium nitride (GaN), indium nitride (InN), aluminum gallium nitride, indium gallium nitride, indium aluminum nitride, and aluminum indium gallium nitride.
